(19) United States
(12) Patent Application Publication
(10) Pub. No.: US 2011/0037454 A1
(43) Pub. Date: Feb. 17, 2011

(54) CdSe QUANTUM DOTS DOPED OPTICAL FIBER AND A CURRENT SENSOR USING THE SAME

(76) Inventors: Won Taek Han, Buk-Gu (KR); Pramod R. Watekar, Buk-Gu (KR); Seong Mi Ju, Buk-Gu (KR); Ho Young Yang, Gwangsan-gu (KR)

Correspondence Address: CHRISTOPHER P. MAIORANA, P.C., 24840 HARPER SUITE 100, ST. CLAIR SHORES, MI, 48080, US

(21) Appl. No.: 12/540,412

(22) Filed: Aug. 13, 2009

(51) Int. Cl. G01R 31/00; G02B 6/00

(52) U.S. Cl. 324/96; 385/142

(57) ABSTRACT

Disclosed is an optical fiber for a current sensor, the optical fiber comprising a core doped with CdSe quantum dots and a current sensor using the same.

### BACKGROUND OF THE INVENTION

1. Field of the Invention

The present invention relates to a CdSe quantum dots doped optical fiber and a current sensor using the same.

2. Background of the Related Art

Current sensors have been studied for quite some time because of their applications in the electrical and the optical devices such as an optical switch, a modulator, non-reciprocal elements in a laser gyroscope, a circulator, and an isolator, etc.

In this regard, glasses containing a large amount of rare-earth ions such as Eu²⁺, Ce³⁺ and Tb³⁺ have been reported for large Faraday effects.

Bulk glass current sensors and their sensitivity improvement technique employing a ferromagnetic field concentrator has been earlier reported.

Bulk current sensors to sense high magnitude of current were realized by using the quartz glass and in another research, simultaneous current and temperature sensing was carried out.

However, as reported, the bulk glass current sensors need bulk optical devices such as polarizers, birefringent plates, special launching lenses, which need precision alignment and careful handling.

To overcome problems faced by bulk sensors, the optical fiber based current sensors have been proposed using fiber Bragg gratings (FBG) based fiber optic arrays and pump signals, which suffer from drawbacks such as a temperature sensitivity, handling difficulties, and an added cost in terms of pumping power and use of infrared sources.

Using the single mode optical fiber has an advantage of portability because no bulk optics (containing lenses, a glass polarizer, etc) are needed to couple light in or out of the fiber. Its light weight, small size, and compatibility with existing light devices such as laser diodes and detectors, make the single mode optical fiber a very compact device if used for a Faraday rotator.

However, a main disadvantage of the optical fiber is that it is less sensitive to the magnetic effect, e.g., silica optical fibers show limited magnetic sensitivity in terms of Verdet constant (˜−0.64 rad T⁻¹ m⁻¹ at 1550 nm and −0.22 rad/T·m at 1310 nm) and there were some attempts to improve the magnetic sensitivity by doping optical fiber core with Eu²⁺ ions, where the Verdet constant was measured to be about −0.9 rad T⁻¹ m⁻¹ at 1310 nm.

### SUMMARY OF THE INVENTION

Accordingly, the present invention has been made in an effort to solve the problems occurring in the prior art. It is an object of the invention to provide a new optical fiber for a current sensor, which was very sensitive to the magnetic field and whose absorption peak matched with the red light wavelength, and a current sensor using the same.

To achieve the above objects, according to an aspect of the invention, there is provided an optical fiber for a current sensor, the optical fiber comprising a core doped with CdSe quantum dots.

Preferably, the CdSe quantum dots have about 5 nm of size in average.

Preferably, the core is an alumino-germano-silica glass.

According to another aspect of the invention, there is provided a current sensor using a CdSe quantum dots doped optical fiber, the current sensor comprising: a light source; a linear polarizer coupled to the light source; a collimator couple to the linear polarizer; a optical fiber having a core doped with CdSe quantum dots, one end of which is coupled to the polarizer; a drum made of insulator and having a hollow portion, on which the optical fiber is wounded with the optical fiber being twisted to have circular polarization in the optical fiber; a polarimeter coupled to the other end of the optical fiber; a photodetector connected to the polarimeter; and a conductor inserted in the hollow portion of the drum and carrying a current.

Preferably, the CdSe quantum dots have about 5 nm of size in average.

Preferably, the core is made of an alumino-germano-silica glass.

Preferably, the insulator is a plastic material.

Preferably, the photodetector comprises a personal computer for analyzing and displaying the Faraday rotation angle using built-in software.

The present invention can provide a new optical fiber doped with CdSe quantum dots, which was very sensitive to the magnetic field and whose absorption peak matched with the red light wavelength.

Also, the present invention can provide a new optical fiber current sensor using a CdSe quantum dots doped optical fiber (for example, with large Verdet constant of about 3.86 rad T⁻¹m⁻¹ at 633 nm for remote sensing the current from 0 to 40 Amperes).

### BRIEF DESCRIPTION OF THE DRAWINGS

FIG. 1 is a cross-sectional view of a CdSe quantum dots doped optical fiber according to the present invention;

FIG. 2 shows spectral transmission characteristics of the CdSe quantum dots doped optical fiber according to the present invention;

FIG. 3 shows schematic diagram of the experimental setup for the Faraday rotation measurement according to the present invention;

FIG. 4 shows variations of the Faraday rotation angle with respect to the applied magnetic field measured at 632 nm for the CdSe quantum dots optical fiber according to the present invention and the conventional (undoped) single mode optical fiber (Both fiber length=71 cm);

FIG. 5 shows an preferred embodiment of remote current sensor using the CdSe quantum dots doped optical fiber of the present invention; and

FIG. 6 shows Measured Faraday rotation angles at various current values flowing through the conductor. Continuous lines show the linear fit. There were 212 fiber loops with 7.5 cm radius around the drum.

### DETAILED DESCRIPTION OF THE PREFERRED EMBODIMENT

Hereinafter, exemplary embodiments of the invention will be explained in details with reference to the accompanying drawings.

With regard to semiconductor quantum dots, the CdS quantum dots doped glasses have shown a high magnetic sensitivity, although this has not yet been tried for the optical fibers.

It can be stated that, to build a current sensor device that is compact, handy, easy to handle and more important, cost effective, a special single mode optical fiber that has a high magnetic sensitivity is needed and it should operate at low cost pumping sources such as visible light emitting diodes or gas lasers.

With this motivation, we demonstrated a current sensor developed with the optical fiber doped with CdSe quantum dots, which was very sensitive to the magnetic field and whose absorption peak matched with the red light wavelength, it was single mode at the peak absorption wavelength and showed about 60 times more sensitivity to the magnetic field than the single mode optical fiber.

Theory

According to the Maxwell's theory, light is composed of both right and left circularly polarized waves, which are superposed and have same frequency. In the absence of magnetic field, these two waves travel in a glass at a same speed. Absorption of light occurs in glasses at specific resonance frequencies, based upon the composition of the material and the electronic structure of constituent atoms. If the magnetic field is imposed on the glass, two closely-spaced resonance frequencies are created by splitting of the original resonance due to a well-known Zeeman-effect. These frequencies correspond to the right and the left circularly polarized light. If a clockwise or a counterclockwise circularly polarized wave travels faster than the other, it would lead to a net rotation of a plane of polarization. When an angle of rotation is clockwise (positive angle), the rotation refers to a diamagnetic rotation. If the rotation is in opposite direction (negative angle) then it is a paramagnetic rotation. The rotation of polarization angle can be expressed as a function of relative susceptibilities of the right and the left circularly polarized light:

$$θ = \frac{4 π}{λ} [ \frac{{( {n}^{2} + 2 )}^{2}}{n} ] ( {χ}_{+} - {χ}_{-} ) L \qquad ( 1 )$$

where λ is the wavelength, n is the refractive index of the material, χ is the electric susceptibility of the polarized light, and L is path length in the medium over which the field interacts with the light. When the plane of polarization of the light beam passes through the medium that is under uniform magnetic field parallel to the light propagation direction, it rotates by angle θ that is given by a well-known expression,

θ=VBL (2)

where θ is the rotation angle of polarization plane of light, B is the magnetic field
(generated by the electric current to be measured), and V is the Verdet constant of the material, which is dependent upon the wavelength of the light used in measurements.

Fabrication of Optical Fibers

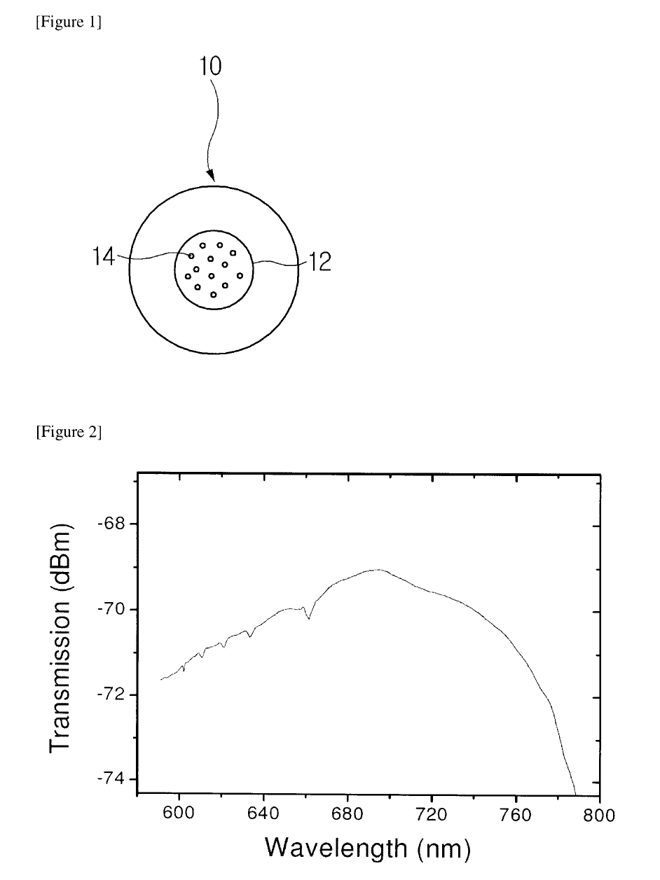

The CdSe QDs-doped optical fiber 10 as shown in FIG. 1 was made by using a modified chemical vapor deposition (MCVD) process. A core 12 of an alumino-germano-silica glass preform was doubly doped at room temperature with a toluene solution containing CdSe quantum dots 14 (Sigma-Aldrich: Lumidot CdSe QDs in toluene, peak absorption ˜650 nm, 7.5 mg in 1.5 ml solution). After the solution doping, subsequent drying of the soaked preform was carried out followed by depositing an additional glass layer to reduce possible evaporation of the dopants. The optical fiber 10 was drawn with outer diameter of 125 μm at 2000° C. using a drawing tower. The optical fiber 10 had a core diameter of 5.36 μm, the GeO₂ concentration of 1.5 mole % in the optical fiber core 12, and a cutoff wavelength of 559 nm. Estimation concentration of CdSe quantum dots 14 was about 2.2×10²⁴ m⁻³ with average quantum dots size of about 5 nm. Another single mode optical fiber having cutoff wavelength at 560 nm (index difference=0.006) without any CdSe quantum dots doping was prepared as a reference fiber.

A transmission spectrum of the optical fiber was measured by using the broadband light source and recording output at an optical spectrum analyzer (AQ 6135B: Ando, Japan). Spectral variation of the transmission is shown in FIG. 2, where a prominent absorption peak at 662 nm along with a series of small peaks below this wavelength can be observed due to CdSe QDs in the optical fiber core. A multi-peak absorption was probably due to non-uniform quantum dots size.

Determination of the Verdet Constant

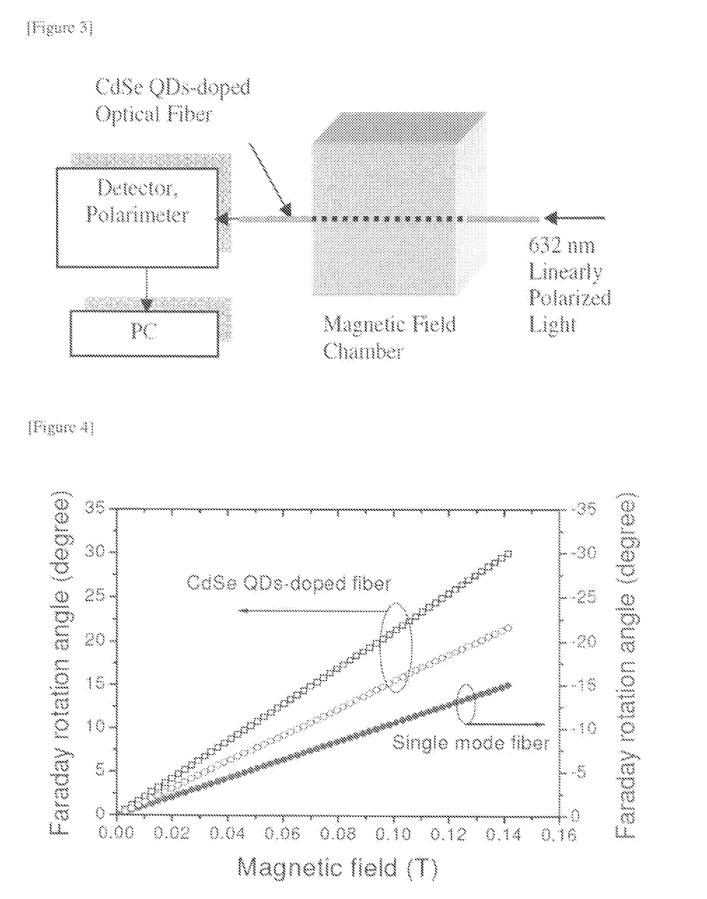

Initially, we measured the Verdet constant of the single mode optical fiber which was not doped with CdSe quantum dots. Optical fiber with length of 71 cm was used where linearly polarized laser emission at 632 nm was launched into the straight fiber kept under the variable magnetic field. The Faraday rotation angle was measured (as shown in a schematic of FIG. 3) by using a polarimeter (PA530: Thorlabs, USA) where the magnetic field strength up to 0.14 T was applied, and a He—Ne laser operating at 632 nm (linearly polarized) was used as a light source. Change in the Faraday rotation angle with change in magnetic field was recorded and used in Eq. (2) to determine the Verdet constant. Typical Faraday rotation for the single mode optical fiber (undoped with CdSe QDs) is shown in FIG. 4 at the wavelength of 632 nm. Faraday rotation angle was quite linear with the applied magnetic field and the Verdet constant for the SMF at 632 nm was −2.7 rad/(T·m).

To determine the Verdet constant of the CdSe quantum dots-doped optical fiber, we chose various samples from different sections of the CdSe QDs-doped optical fiber from over 500 m of length so that more accurate average prediction of the Verdet constant can be carried out. It is noted that Faraday rotation angle was in the range of 22 degrees to 30 degrees, for the CdSe QDs-doped optical fiber's random samples. These variations in the Faraday rotation angles indicate that the CdSe concentration in the optical fiber core was not uniform. The Verdet constant values for these data varied from about 3.9 to 5.3 rad T−1m−1. Therefore it can be stated that the magnetic sensitivity of the CdSe quantum dots doped optical fiber was about 1.5 to 2 times higher than the undoped optical fiber.

Current Sensitivity

Twisting of optical fibers has been already used to enhance the current sensitivity of optical fibers. In fact, it has been observed that in the spun fibers, sensitivity reaches the value for the ideal isotropic fiber. Here we define the sensitivity of the current sensor by using the variation in the Faraday rotation angle obtained after the current was applied:

$$S = \frac{θ}{IN} \qquad ( 3 )$$

And ideal unit turn sensitivity for the isotropic fiber equals:

S=μ₀V (4)

where S is the sensitivity, θ is the Faraday rotation angle in radians, V is the Verdet constant in rad/T·m, N is the number of turns and μ0 (=4π×10⁻⁷ T·m/A) is the permeability of fiber. Relationship between sensitivity of the current sensor and optical fiber's Verdet constant can be used to determine the maximum current sensitivity possible with the optical fiber.

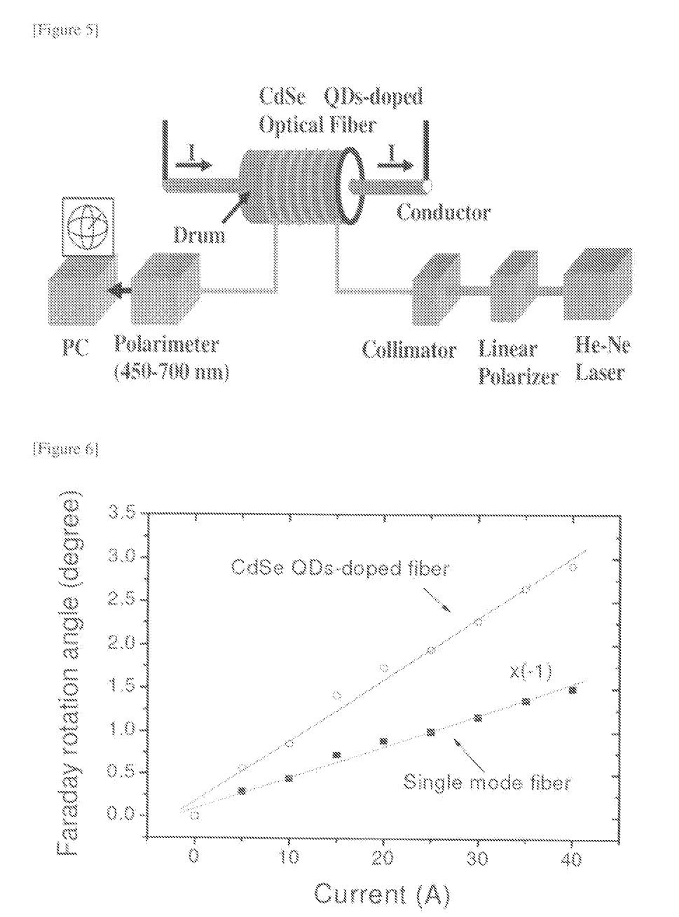

An experimental arrangement for the current sensor using optical fibers is shown in FIG. 5. The He—Ne laser emitting at 632 nm (10 mW) was used as the input source. The linearly polarized light at 632 nm was launched into the optical fiber using a collimator. The optical fiber (100 m) was twisted manually with 8 twists per meter to have circular polarization in the optical fiber and then it was wound on a plastic drum (15 cm diameter). Its output was directly launched into a photo detector that was a part of the polarimeter. The polarimeter's output was fed to a personal computer (PC), which displayed the Faraday rotation angle using the built-in software. A conductor carrying a high current of 40 A was inserted in the hollow portion of the drum. Flow of current through the conductor generated the self-induced magnetic field, which influenced the Faraday rotation angle of the optical fiber.

FIG. 6 shows variation of the Faraday rotation angle with respect to applied current for the single mode optical fiber (undoped) at 632 nm. It is noted that for 100 m of optical fiber, one needs 212 fiber loops of 15 cm diameter. From FIG. 6, it is observed that the current sensitivity of the undoped single mode fiber was calculated to be 3.1×10⁻⁶ rad/A for one loop of 15 cm diameter. By replacing the undoped single mode fiber with the CdSe QDs-doped optical fiber in FIG. 5, we carried out the Faraday rotation measurement with respect to various current values. As shown in FIG. 6, the current sensitivity of the CdSe QDs-doped optical fiber was estimated using Eq. (3) to be 6×10⁻⁶ rad/A for one loop of 15 cm diameter.

A relationship between the current and the Faraday rotation angle is shown in FIG. 6 for our current sensor where the CdSe QDs-doped optical fiber was wound on a drum and it had total length of 100 m kept under the influence of magnetic field. It was possible to detect the current remotely by using our current sensor; we applied up to 40 A of current in different steps. The sensitivity of the current sensor was found to be 6.0×10⁻⁶ rad/A at 632 nm.

First point of our discussion is: Is the CdSe QDs-doped optical fiber really superior to reported optical fibers? To answer this question, we performed the Verdet constant measurement of the CdSe QDs-doped optical fiber and the undoped single mode fiber at 632 nm as described in the previous section. Comparison of the Verdet constants measured for various optical fibers has been listed in Table 1. The Verdet constant value of the CdSe QDsdoped optical fiber was about two times larger as compared to that of the undoped single mode optical fiber can be noticed from Table 1, indicating the superiority of the CdSe QDsdoped optical fiber in terms of its enhanced Faraday effect.

TABLE 1
Comparision of Verdet constant of various
optical fibers and silica glass at 632

| CdSe quantum dots | Single mode undoped | |
|---|---|---|
| doped optical fiber | fiber | Silica glass |
| (Present invention) | (Comparative) | (Comparative) |
| 5.3 rad T⁻¹m⁻¹ | −2.7 rad T⁻¹ m⁻¹ | −3.4 rad T⁻¹m⁻¹ |

Next, with regard to the current sensitivity of our current sensor where the twisted CdSe QDs-doped optical fiber and undoped single mode optical fiber were wound on a spool (8 twists per meter, 212 windings, and 15 cm diameter); the single mode optical fiber showed the current sensitivity (for one loop) of about 3.1 μrad/A at 632 nm as compared to the current sensitivity of about 6.0 μrad/A at 632 nm for the CdSe QDs-doped optical fiber for one loop. Thus, addition of CdSe QDs in the single mode optical fiber has enhanced the sensitivity of the current sensor by about 1.9 times. In the earlier work, for the optical fiber current sensor with the current of 120 A, 26 loops of 15 cm diameter, and 636 nm of operating wavelength had shown the Faraday rotation of about 14 mrad, which gives (from Eq. (3)) the current sensitivity of 4.48 μrad/A for one loop, while in another report, the current sensitivity of about 5.58 μrad/A has been reported for the optical fiber current sensor. The germanium concentration, the fiber structure, experimental conditions causing a small portion of linear polarization to be remained with the circular polarization can degrade the current sensitivity and these can be the cause of difference between current sensitivities of current sensors made with our single mode optical fiber and that of reported fibers. However, it is noted that in our optical fiber current sensors undergoing similar experimental treatment, CdSe QDs-doped optical fiber has shown better performance as shown in Table 2.

TABLE 2
Comparison of current sensor sensitivity of
various optical fibers measured at 632 nm for one loop of
15 cm.

| | CdSe quantum dots | Undoped single mode |
|---|---|---|
| | doped optical fiber | fiber |
| Parameter | (Present invention) | (Comparative) |
| Current sensitivity | 6.0 μrad/A | 3.1 μrad/A |

One more question that arises is the selection of pumping wavelength. As we have shown in FIG. 2, the prominent peak related to the CdSe quantum dots appeared at around 662 nm, and therefore, natural choice of pumping wavelength would be 662 nm. However, as per availability of sources in our laboratory, we used 632 nm. Naturally then how can CdSe quantum dots support high magnetic sensitivity at a wavelength far from its resonant absorption peak? To answer this question, we need to note that prominent absorption peak was at 662 nm and it was supported by minor peak structures at 623 nm and 632 nm as shown in FIG. 2. This arises due to non-uniformity of sizes of the quantum dots. It is true that more improved performance could have been obtained at 662 nm, however, 632 nm pumping of the CdSe QDs-doped optical fiber has also given reasonably better performance than the undoped single mode optical fiber.

Regarding high magnetic sensitivity of the CdSe QDs-doped optical fiber, it can be stated that in general terms the Faraday effect arises due to different indices of refraction for the right and the left circularly polarized light (n+ and n−). As per classical equation of motion of a valence electron in the magnetic field,

$${n}_{\pm } = \sqrt{1 - \frac{{N}_{e} / ( m {ɛ}_{0} )}{( {ω}_{0}^{2} - {ω}^{2} ) m {ω}_{c} ω}} \qquad ( 5 )$$

where N is total valence electrons, e is an electronic charge, m is the mass of electron, ∈₀ is the dielectric constant, ω is an operating frequency, ω₀=\sqrt{mk} with κ being the spring constant to a fixed atomic site, and ω_{c} is a cyclotron frequency. Eq. (5) shows that left and right circular refractive indices are influenced by the cyclotron frequency and therefore, by the magnetic field. In terms of quantum mechanics, n± are dependent upon transitions between polarization states and their differing energy levels. Interaction of a photon with the right-circular polarization can cause electrons in spin-down (−½) states to make transition to spin-up (+½) states. Similarly, the left-circular polarization can cause electrons states to make transitions from ½ states to +½ states. Superposition of these effects of electronic transitions gives the Faraday effect. In quantum dots, infinite potential wells cause excitons and electrons to experience confinement energies as the quantum dot size reduces. A strong confinement influences the exchange interaction of electrons and holes, which mixes different electron and hole spin states causing modifications in the Verdet constant.

In addition to the high current and magnetic sensitivity, as the CdSe QDs-doped optical fiber had LP₁₁ cutoff wavelength of 559 nm, it was possible to use visible light at 632 nm as a signal in the current sensor. The current sensor can be made more sensitive by increasing the concentration of CdSe QDs in the optical fiber. Bulk glasses doped with CdSe quantum dots with QD density in the range of 1026 particles/m3 show a high V and therefore, they are good candidates to develop current sensors. However in the optical fibers, increasing QDs concentration will increase the attenuation and one will have to find an optimum balance in the concentration of QDs and the allowed attenuation.

In summary, we demonstrated the current sensor by using the optical fiber doped with CdSe quantum dots, which showed the current sensitivity of about 296.7 μrad/A at 632 nm. We were able to sense the current up to 40 A. The presented current sensor device can be useful for measuring the current remotely for various applications including power lines carrying heavy voltage and current.

Although the present invention has been described with reference to the preferred embodiment, the description is illustrative of the invention and is not to be construed as limiting the invention. Various modifications and variation may occur to those skilled in the art, without departing from the spirit and scope of the invention, as defined by the appended claims.

What is claimed is:

1. An optical fiber for a current sensor, the optical fiber comprising a core doped with CdSe quantum dots.

2. The optical fiber of claim 1, wherein the CdSe quantum dots have about 5 nm of size in average.

3. The optical fiber of claim 1, wherein the core is an alumino-germano-silica glass.

4. A current sensor using a CdSe quantum dots doped optical fiber, the current sensor comprising:
a light source;
a linear polarizer coupled to the light source;
a collimator couple to the linear polarizer;
a optical fiber having a core doped with CdSe quantum dots, one end of which is coupled to the polarizer;
a drum made of insulator and having a hollow portion, on which the optical fiber is wounded with the optical fiber being twisted to have circular polarization in the optical fiber;
a polarimeter coupled to the other end of the optical fiber;
a photodetector connected to the polarimeter; and
a conductor inserted in the hollow portion of the drum and carrying a current.

5. The current sensor of claim 4, wherein the CdSe quantum dots have about 5 nm of size in average.

6. The current sensor of claim 4, wherein the core is an alumino-germano-silica glass.

7. The current sensor of claim 4, wherein the insulator is a plastic material.

8. The current sensor of claim 4, wherein the photodetector comprises a personal computer for analyzing and displaying the Faraday rotation angle using built-in software.
